(19) United States
(12) Patent Application Publication
(10) Pub. No.: US 2026/0165080 A1
(43) Pub. Date: Jun. 11, 2026

(54) DRIVE DEVICE, POSITIONING DEVICE, PROCESSING DEVICE, AND DEVICE MANUFACTURING METHOD

(71) Applicant: SUMITOMO HEAVY INDUSTRIES, LTD., Tokyo (JP)

(72) Inventors: Naoto MUROI, Yokosuka-shi (JP); Tatsuya YOSHIDA, Yokosuka-shi (JP); Taro WATANABE, Yokosuka-shi (JP)

(21) Appl. No.: 19/408,094

(22) Filed: Dec. 3, 2025

(30) Foreign Application Priority Data
Dec. 5, 2024 (JP) 2024-212266

(51) Int. Cl. H01L 21/68; B65G 51/03; B65G 54/02

(52) U.S. Cl. CPC H10P 72/50; B65G 51/03; B65G 54/02

(57) ABSTRACT

A drive device includes a first drive shaft driving a driven body in a first direction, and a second drive shaft driving the driven body and the first drive shaft in a second direction intersecting the first direction. The second drive shaft includes a guide extending in the second direction and a slider movable along the guide. An end portion of the first drive shaft is provided to face one side surface of the slider, and a movable element of a linear motor applying a driving force in the second direction to the slider is provided to face the other side surface. A connection member connecting the end portion and the movable element is provided above the slider. A load receiving portion receiving a load from the connection member is provided between an upper surface of the slider and the connection member.

### CROSS-REFERENCE TO RELATED APPLICATIONS

This application claims priority to Japanese Patent Application No. 2024-212266, filed on December 5, 2024, which is incorporated by reference herein in its entirety.

### BACKGROUND

### TECHNICAL FIELD

Certain embodiments of the present disclosure relate to a drive device and the like.

### DESCRIPTION OF RELATED ART

The related art discloses a drive device or an actuator used in a vacuum environment, which includes a slider driven along a predetermined movement direction by a gas pressure inside an air servo chamber, and a guide extending in the movement direction to guide the slider. The slider can smoothly move while floating from the guide by an air bearing formed by compressed air supplied between an outer periphery of the slider and an inner periphery of the guide through an air pad.

### SUMMARY

According to an embodiment of the present disclosure, there is provided a drive device including a first drive shaft that drives a driven body in a first direction, and a second drive shaft that drives the driven body and the first drive shaft in a second direction intersecting the first direction. The second drive shaft includes a guide extending in the second direction and a slider movable along the guide. An end portion of the first drive shaft is provided to face one side surface of the slider, and a movable element of a linear motor that applies a driving force in the second direction to the slider is provided to face the other side surface of the slider. A connection member that connects the end portion of the first drive shaft and the movable element of the linear motor is provided above the slider. A load receiving portion that receives a load from the connection member is provided between an upper surface of the slider and the connection member.

According to the present embodiment, the high responsiveness of the second drive shaft can be realized by the linear motor, and the load receiving portion and the upper surface of the slider can appropriately receive the load from the connection member by the linear motor or the like.

According to another embodiment of the present disclosure, there is provided a positioning device. The device positions the driven body by using the drive device described above.

According to still another embodiment of the present disclosure, there is provided a processing device. The device performs predetermined processing on a workpiece disposed on the driven body positioned by the positioning device.

According to yet another embodiment of the present disclosure, there is provided a device manufacturing method. In the method, a device is manufactured through processing performed by the processing device.

Any combination of the above-described components or any conversion of these components into a method, a device, a system, a recording medium, a computer program, or the like is also encompassed by the present disclosure.

### BRIEF DESCRIPTION OF THE DRAWINGS

FIG. 1 is a perspective view schematically illustrating a stage device.

FIG. 2 is a perspective view schematically illustrating details of a first linear motor.

FIG. 3 is a section view schematically illustrating a first gas floating portion that enables a first drive shaft to smoothly drive an X-slider in an X-axis direction by using a floating gas.

FIG. 4 is a section view schematically illustrating a second gas floating portion that enables a second drive shaft to smoothly drive a Y-slider in a Y-axis direction by using the floating gas.

FIG. 5 is a ZX-plane view schematically illustrating a connection portion between the first drive shaft and the second drive shaft.

### DETAILED DESCRIPTION

In a gas pressure actuator as disclosed in the related art, there is a disadvantage in that responsiveness or fast response is less likely to be improved when the slider is driven due to physical limitations based on a principle of converting a gas pressure in the air servo chamber into a thrust of the slider.

It is desirable to provide a drive device and the like which can appropriately cope with a load caused by a linear motor or the like while improving responsiveness when a linear motor drives a driven body.

Hereinafter, modes (hereinafter, also referred to as embodiments) for carrying out the present disclosure will be described in detail with reference to the drawings. In the description and/or the drawings, the same reference numerals will be assigned to the same or equivalent components, members, processes, and the like, and repeated description thereof will be omitted. A scale or a shape of each element illustrated in the drawings is set for convenience to simplify the description, and should not be construed in a limiting sense unless particularly specified. The embodiments are merely examples, and do not limit the scope of the present disclosure in any way. All features or combinations thereof presented in the embodiments are not necessarily essential to the present disclosure. For convenience, the embodiments are presented by being decomposed into components for each function and/or each function group that realize the embodiments. However, one component in the embodiments may actually be realized by a combination of a plurality of components serving as separate bodies, or a plurality of components in the embodiments may actually be realized by a single integral component. In addition, a plurality of embodiments or modification examples may be disclosed in parallel. However, any components of each embodiment and/or each modification example may be combined in any manner as long as functions do not hinder each other.

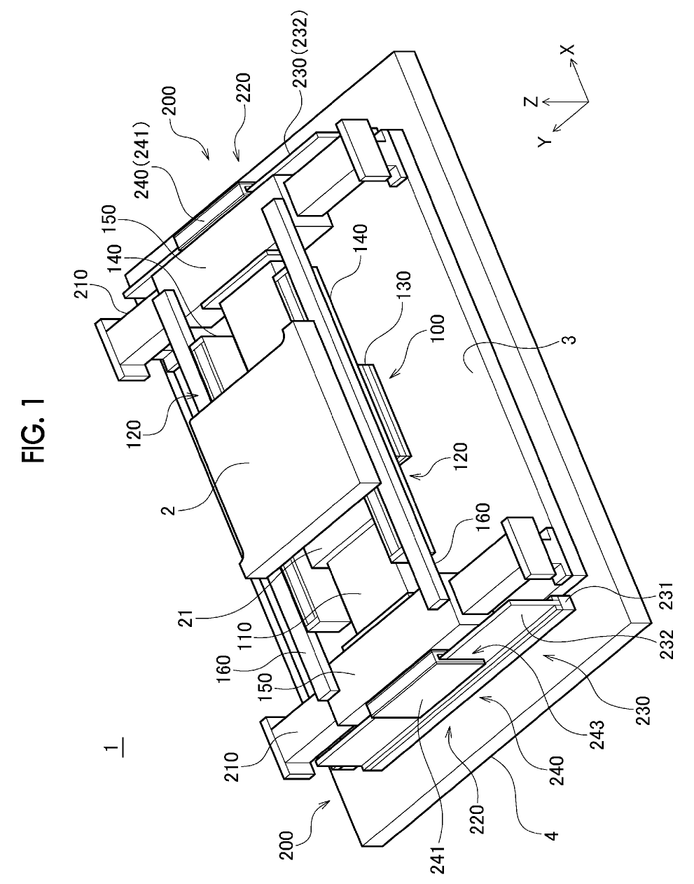

FIG. 1 is a perspective view schematically illustrating a stage device 1 serving as a drive device or a positioning device according to an embodiment of the present disclosure. In the present embodiment, for convenience, a three-dimensional coordinate system or an XYZ-coordinate system formed by an X-axis, a Y-axis, and a Z-axis which are perpendicular to each other is set. An X-axis direction is a first direction serving as a driving direction in which a first drive shaft 100 (to be described later) drives a stage 2 or a table serving as a driven body. A Y-axis direction is a second direction serving as a driving direction in which a second drive shaft 200 (to be described later) integrally drives the stage 2 and the first drive shaft 100. A Z-axis direction is a third direction serving as a normal direction of a drive plane or an XY-plane formed by the X-axis and the Y-axis. The XY-plane is preferably a horizontal plane, and the Z-axis direction in this case is a vertical direction. The X-axis, the Y-axis, and the Z-axis may not be perpendicular to each other, and may intersect each other at least. In other words, the X-axis direction, the Y-axis direction, and the Z-axis direction may be different from each other.

The stage device 1 includes a first drive shaft 100 that drives the stage 2 in the X-axis direction by using a magnetism, and a second drive shaft 200 that integrally drives the stage 2 and the first drive shaft 100 in the Y-axis direction by using the magnetism. In an example of the present embodiment, a pair (that is, two) of substantially the same second drive shafts 200 are provided in both end portions of the first drive shaft 100 extending in the X-axis direction. Hereinafter, unless otherwise specified, the two second drive shafts 200 will be collectively described without being distinguished therebetween.

One first drive shaft 100 and two second drive shafts 200 form a substantially H-shape when viewed in the Z-axis direction or when viewed from above. The two second drive shafts 200 are fixedly installed on the front surface of a surface plate 3 having the front surface in the XY-plane or a horizontal plane. One first drive shaft 100 is in a non-contact state separated from the front surface of the surface plate 3 in the Z-axis direction such that the first drive shaft 100 can move on the surface plate 3 in the Y-axis direction through the two second drive shafts 200. The surface plate 3 is further fixedly installed on the front surface of a base 4 having the front surface in the XY-plane or the horizontal plane.

Any object (not illustrated) is placed on a front surface of the stage 2 forming the driven body. Here, the "front surface" or a "top surface" in the present embodiment represents a surface on a +Z side (upper surface in FIG. 1), and a "back surface" or a "bottom surface" in the present embodiment represents a surface on a −Z side (lower surface in FIG. 1). In addition, with regard to the first drive shaft 100 in which the X-axis direction is a driving direction, a surface on a ±Y side is represented as a “side surface”, and a surface on a ±X side is represented as a “front surface” or a “rear surface”. Similarly, with regard to the second drive shaft 200 in which the Y-axis direction is the driving direction, the surface on the ±X side is represented as the “side surface”, and the surface on the ±Y side is represented as the “front surface” or the “rear surface”.

Any workpiece such as a semiconductor wafer may be placed on the front surface or the top surface of the stage 2. The stage device 1 in this case forms a positioning device that positions a workpiece placed on the stage 2 serving as the driven body, and further forms a part of a processing device that performs any processing on the workpiece positioned by the positioning device. Examples of the processing device include a semiconductor manufacturing device or a flat panel display (FPD) manufacturing device such as an exposure device, an ion implanter, a heat treatment device, an ashing device, a sputtering device, a dicing device, an inspection device, and a cleaning device.

The first drive shaft 100 that drives the stage 2 serving as the driven body in the X-axis direction includes an X-guide 110 linearly extending along the X-axis direction. The X-guide 110 forms a main body of the first drive shaft 100. An X-slider 21 which is linearly movable or slidable along the X-axis direction (predetermined driving direction) while being guided by the X-guide 110 is provided on the X-guide 110. A front surface (surface on the +Z side) of the X-slider 21 is connected to the back surface (surface on the −Z side) of the stage 2, and integrally forms the driven body. Therefore, the stage 2 is movable in the X-axis direction while being guided by the X-guide 110, integrally with the X-slider 21. As will be described later, a floating gas such as compressed air is supplied between an inner peripheral surface of the X-slider 21 forming the driven body and an outer peripheral surface of the X-guide 110 forming the first drive shaft 100. Therefore, the X-slider 21 can float from the X-guide 110, and can smoothly move in a substantially non-contact state.

A first linear motor 120 serving as a drive unit is formed between the driven body and the first drive shaft 100 to drive the driven body formed by the stage 2 and the X-slider 21 along the X-axis direction. The first linear motor 120 applies a driving force along the X-axis direction (driving direction) to the X-slider 21. In the present embodiment, a pair (that is, two) of substantially the same first linear motors 120 are provided on both sides of the X-slider 21 serving as the driven body (and the X-guide 110 serving as the main body of the first drive shaft 100) in the Y-axis direction. In addition, each of the first linear motors 120 is provided in the X-slider 21 on the back surface side of the driven body formed by the stage 2 and the X-slider 21. In this way, each of the first linear motors 120 is provided in the X-slider 21 on a back surface side separated from the stage 2 on a front surface side. In this manner, it is possible to reduce an adverse effect that magnetism leaked from each of the first linear motors 120 may affect processing of a semiconductor wafer or the like on the stage 2 (for example, irradiation with an electron beam which is likely to receive influence of the magnetism).

In general, the linear motor includes a coil portion including a plurality of coils through which a current flows from an outside to generate a magnetic field, and a magnet portion including a plurality of magnets acting on the magnetic field generated by the coil portion. The first linear motor 120 according to the present embodiment also includes a first coil portion 130 serving as the coil portion and a first magnet portion 140 serving as the magnet portion. In order to form the first linear motor 120 that drives the X-slider 21 (and the stage 2) serving as the driven body along the X-axis direction, one of the first coil portion 130 and the first magnet portion 140 may be provided in the X-slider 21, and the other may be provided in the first drive shaft 100.

In the first linear motor 120, it is preferable that the first coil portion 130 is provided in the X-slider 21 and the first magnet portion 140 is provided in the first drive shaft 100. As illustrated, the first magnet portion 140 may be attached to a columnar beam portion 160 laid between a pair of Y-sliders 150 (to be described later) which are also a part of the first drive shaft 100. These components may be disposed in any way. However, for example, when viewed in the Z-axis direction, the X-slider 21, the first magnet portion 140 (or the first coil portion 130), and the beam portion 160 are disposed in this order from the X-slider 21 at the center toward the outside in the Y-axis direction. In addition, similarly, the first magnet portion 140 and the beam portion 160, which are long in the X-axis direction, are disposed substantially parallel to both sides in the Y-axis direction of the X-guide 110, which is long in the X-axis direction. However, the first magnet portion 140 and the beam portion 160 are not in contact with the X-guide 110, and the X-slider 21 is movable in a gap therebetween.

The first coil portion 130 is driven in the X-axis direction integrally with the X-slider 21 by magnetic interaction with the first magnet portion 140. Since the first coil portion 130 moves in this way, the first linear motor 120 is a so-called moving coil type linear motor. In this case, since the first magnet portion 140 is stationary in the X-axis direction (however, the first magnet portion 140 is moved in the Y-axis direction by the second drive shaft 200), there is an advantage in that fluctuations in the magnetism leaking outward of the first linear motor 120 are small. This is particularly preferable when the processing of the semiconductor wafer or the like on the stage 2 is likely to be affected by the magnetism.

In this moving coil type first linear motor 120, a length of the first coil portion 130 in the X-axis direction is shorter than a length of the first magnet portion 140 in the X-axis direction. For example, it is preferable that the length of the first coil portion 130 in the X-axis direction is equal to or shorter than the length of the X-slider 21 and/or the stage 2 in the X-axis direction. In addition, it is preferable that the length of the first magnet portion 140 in the X-axis direction is the length that can cover a movable range of the X-slider 21 in the X-axis direction. As will be described later, the relatively short first coil portion 130 can move in the X-axis direction integrally with the X-slider 21 and the stage 2 serving as the driven body within an installation range of the relatively long first magnet portion 140.

On the other hand, when the processing of the semiconductor wafer or the like on the stage 2 is less likely to be affected by the magnetism, the first linear motor 120 may be formed as a so-called moving magnet type. Specifically, the first coil portion 130 is provided in the first drive shaft 100 (for example, the beam portion 160), and the first magnet portion 140 is provided in the X-slider 21 (not illustrated). In this case, the first coil portion 130 that generates heat due to a flowing current is isolated from the driven body integrated with the stage 2 or the X-slider 21. Therefore, heat transfer to the stage 2 and/or a workpiece such as the semiconductor wafer can be effectively suppressed. This is particularly preferable when a workpiece such as a semiconductor wafer is likely to be affected by the heat.

In this moving magnet type first linear motor 120, the length of the first coil portion 130 in the X-axis direction is longer than the length of the first magnet portion 140 in the X-axis direction. For example, it is preferable that the length of the first coil portion 130 in the X-axis direction is the length that can cover a movable range of the X-slider 21 in the X-axis direction. In addition, it is preferable that the length of the first magnet portion 140 in the X-axis direction is equal to or shorter than the length of the X-slider 21 and/or the stage 2 in the X-axis direction. The relatively short first magnet portion 140 can move in the X-axis direction integrally with the X-slider 21 and the stage 2 serving as the driven body within an installation range of the relatively long first coil portion 130.

Since the pair of first linear motors 120 formed in this way are provided on both sides in the Y-axis direction of the X-slider 21 and the stage 2 serving as the driven body, the driven body can be stably driven in the X-axis direction while an undesirable rotation such as yawing (rotation around the Z-axis) can be effectively suppressed.

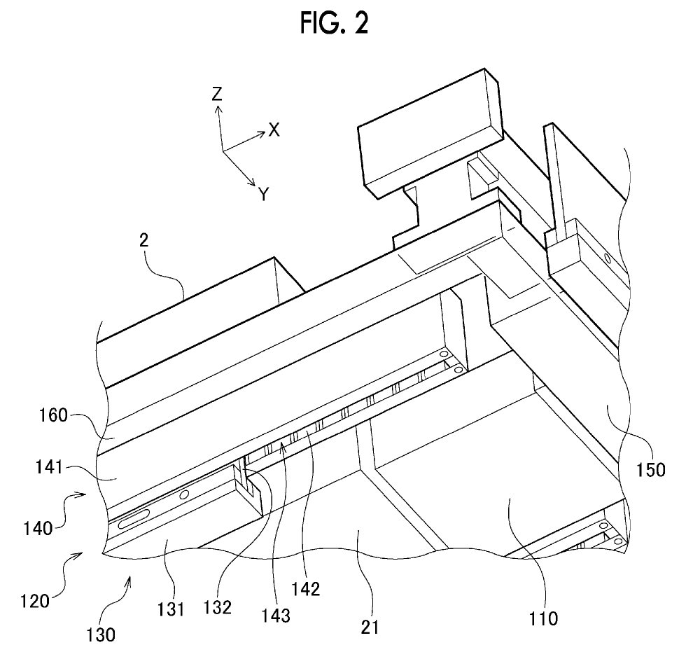

FIG. 2 is a perspective view schematically illustrating details of the first linear motor 120. This drawing is obtained when the first linear motor 120 in FIG. 1 is viewed from a back surface side (−Z side).

The first coil portion 130 includes a holder 131 and a coil 132 held by the holder 131. Although detailed illustration is omitted, for example, the coil 132 is a general three-phase coil. Specifically, a U-phase coil, a V-phase coil, and a W-phase coil (not illustrated) are periodically disposed along the X-axis direction which is the driving direction. A current (for example, a U-phase current, a V-phase current, and a W-phase current) flowing through the coil 132 in each phase may be supplied via the holder 131. The coil 132 is provided to protrude from the holder 131 on a back surface side toward a front surface side (+Z side). It is preferable that this coil 132 or a coil group is formed in a flat plate shape in which the Y-axis direction is a normal direction, as a whole. Preferably, the holder 131 is fixedly attached to a side surface on the back surface side of the X-slider 21 serving as the driven body. Therefore, the first coil portion 130 is movable in the X-axis direction integrally with the X-slider 21.

The first magnet portion 140 includes a substantially rectangular parallelepiped casing 141 and magnets 142 arrayed on an inner peripheral surface of the casing 141. For example, the casing 141 is formed of a magnetic shielding material such as carbon steel or permalloy or a soft magnetic material. A long opening 143 extending in the X-axis direction is formed on the back surface of the casing 141 over substantially the entire length thereof (front surface of the casing 141 is closed by the magnetic shielding material or the like). Although explicit illustration is omitted, a magnetic shielding portion may be provided on an edge portion of the opening 143 or a side surface of the casing 141. The above-described flat plate-shaped coil 132 is inserted into a substantially rectangular parallelepiped space inside the casing 141 formed by the opening 143. In addition, the magnets 142 such as permanent magnets in which magnetic poles are periodically changed are arrayed along the X-axis direction on an inner peripheral surface of the casing 141, which is a side wall surface of the space.

In this way, the coil 132 or the coil group in the first coil portion 130 and the magnet 142 or the magnet group in the first magnet portion 140 face each other in the Y-axis direction in the substantially rectangular parallelepiped space inside the casing 141. The coil 132 that functions as an electromagnet through which a three-phase alternating current or the like flows magnetically interacts with the magnet 142, thereby generating a thrust or a driving force for driving the coil 132 as a movable element in the X-axis direction. The flat plate-shaped coil 132 is driven along the X-axis direction in the substantially rectangular parallelepiped space inside the casing 141. The X-slider 21 and the stage 2 serving as the driven body to which the coil 132 or the first coil portion 130 is fixed are also driven in the X-axis direction integrally with the first coil portion 130 while being guided by the X-guide 110.

As described above, in an example in FIG. 2, the coil 132 through which a current flows is provided to protrude from the holder 131 toward the front surface side (+Z side), and the first magnet portion 140 or the magnet 142 acting on the magnetic field generated by the coil 132 is provided to cover the coil 132 from the front surface side. In this first linear motor 120, the opening 143 through which the magnetism from the coil 132 and/or the magnet 142 leaks is provided on the back surface side far from the stage 2. Therefore, it is possible to reduce an adverse effect that the magnetism may affect on the processing of the semiconductor wafer or the like on the stage 2.

In FIG. 1, the stage 2 and the X-slider 21 serving as the driven body and the second drive shaft 200 that integrally drives the first drive shaft 100 in the Y-axis direction include a Y-guide 210 that linearly extends along the Y-axis direction. The Y-guide 210 forms a main body of the second drive shaft 200. A Y-slider 150 which is linearly movable or slidable along the Y-axis direction (predetermined driving direction) while being guided by the Y-guide 210 is provided on the Y-guide 210.

The Y-slider 150 is a part of the second drive shaft 200, and is also a part of the above-described first drive shaft 100. Specifically, a pair (that is, two) of substantially the same Y-sliders 150 are integrally provided in both end portions of the X-guide 110 serving as the main body of the first drive shaft 100 in the X-axis direction. When the pair of second drive shafts 200 drive the pair of Y-sliders 150 in the Y-axis direction, the entire first drive shaft 100 formed integrally with the Y-slider 150 and the stage 2 and the X-slider 21 serving as the driven body are also integrally driven in the Y-axis direction. In this way, a drive target of the second drive shaft 200 includes the entire first drive shaft 100 partially including the Y-slider 150, and the driven body formed by the stage 2 and the X-slider 21.

The stage 2 serving as the driven body is movable integrally with the Y-slider 150 in the Y-axis direction while being guided by the Y-guide 210. As will be described later, a floating gas such as compressed air is supplied between the inner peripheral surface the Y-slider 150 forming the first drive shaft 100 and the outer peripheral surface the Y-guide 210 forming the second drive shaft 200. Therefore, the Y-slider 150 floats from the Y-guide 210, and is smoothly movable in a substantially non-contact state.

In order to drive the drive target including the stage 2 and the Y-slider 150 along the Y-axis direction, a second linear motor 220 serving as the drive unit is formed between the drive target and the second drive shaft 200. The second linear motor 220 applies a driving force to the Y-slider 150 along the Y-axis direction (driving direction). In the present embodiment, a pair (that is, two) of substantially the same second linear motors 220 are provided outside each of the Y-guides 210 and each of the Y-sliders 150 in the X-axis direction.

The second linear motor 220 includes a second coil portion 230 serving as a coil portion and a second magnet portion 240 serving as a magnet portion. In order to form the second linear motor 220 that drives the Y-slider 150 serving as the drive target along the Y-axis direction, one of the second coil portion 230 and the second magnet portion 240 may be provided in the Y-slider 150, and the other may be provided in the second drive shaft 200.

In the second linear motor 220, it is preferable that the second coil portion 230 is juxtaposed in the second drive shaft 200 and the second magnet portion 240 is provided in the Y-slider 150. As illustrated, the second coil portion 230 may be fixedly installed on the base 4 adjacent to the second drive shaft 200. Since the base 4, the surface plate 3, and the second drive shaft 200 are fixed to each other, even when the second coil portion 230 is provided in any of the surface plate 3, and the second drive shaft 200, it should be interpreted that the second coil portion 230 is provided in the second drive shaft 200. The second coil portion 230 (in particular, a coil 232 to be described later) is not in contact with the Y-guide 210 and the Y-slider 150, and the second magnet portion 240 (in particular, a casing 241 to be described later) is movable in the Y-axis direction in a gap therebetween. In this way, the second coil portion 230 is provided at a position separated from the Y-guide 210 serving as the main body of the second drive shaft 200 in the X-axis direction.

The second coil portion 230 includes a holder 231 installed on the base 4, and a coil 232 held by the holder 231. Although detailed illustration is omitted, for example, the coil 232 is a general three-phase coil. Specifically, a U-phase coil, a V-phase coil, and a W-phase coil (not illustrated) are periodically disposed along the Y-axis direction which is the driving direction. A current (for example, a U-phase current, a V-phase current, and a W-phase current) flowing through the coil 232 in each phase may be supplied via the holder 231. The coil 232 is provided to protrude from the holder 231 on the back surface side (−Z side) toward the front surface side (+Z side). It is preferable that this coil 232 or the coil group is formed in a flat plate shape in which the X-axis direction is the normal direction, as a whole. In addition, when viewed in the Z-axis direction, the entire second coil portion 230 and/or the coil 232 extend along the Y-axis direction substantially parallel to the Y-guide 210.

The second magnet portion 240 includes a substantially rectangular parallelepiped casing 241 and magnets (not illustrated) arrayed on an inner peripheral surface of the casing 241. The casing 241 is fixedly attached to a side surface of the Y-slider 150 serving as the drive target in the X-axis direction serving as the normal direction. Therefore, the second magnet portion 240 is movable integrally with the Y-slider 150 in the Y-axis direction.

For example, the casing 241 is formed of a magnetic shielding material such as carbon steel or permalloy or a soft magnetic material. A substantially rectangular parallelepiped space 243 penetrating in the Y-axis direction and open on the back surface is formed inside the casing 241. The casing 241 has an inverted U-shape when viewed in the Y-axis direction. The above-described flat plate-shaped coil 232 is inserted into the substantially rectangular parallelepiped space 243 inside the casing 241. In addition, magnets (not illustrated) such as permanent magnets in which magnetic poles are periodically changed are arrayed along the Y-axis direction on an inner peripheral surface of the casing 241 which is a side wall surface of the space 243.

In this way, the coil 232 or the coil group in the second coil portion 230 and the magnet or the magnet group (not illustrated) in the second magnet portion 240 face each other in the X-axis direction in the substantially rectangular parallelepiped space 243 inside the casing 241. The coil 232 that functions as an electromagnet through which a three-phase alternating current or the like flows magnetically interacts with a magnet (not illustrated) to generate a thrust or a driving force that drives the second magnet portion 240 serving as the movable element in the Y-axis direction. The inverted U-shaped casing 241 when viewed in the Y-axis direction is driven in the Y-axis direction along the flat plate-shaped coil 232 in a state where the flat plate-shaped coil 232 is pinched from above (state where the coil 232 is included in the space 243 inside the casing 241). The Y-slider 150 serving as the drive target to which the casing 241 of the second magnet portion 240 is fixed is also driven in the Y-axis direction integrally with the second magnet portion 240 while being guided by the Y-guide 210.

As described above, in the example in FIG. 1, the coil 232 through which a current flows is provided to protrude from the holder 231 toward the front surface side (+Z side), and the second magnet portion 240 acting on the magnetic field generated by the coil 232 is provided to cover the coil 232 from the front surface side. In this second linear motor 220, the space 243 to which the magnetism leaks from the coil 232 and/or the second magnet portion 240 is provided on the back surface side far from the stage 2. Therefore, it is possible to reduce an adverse effect that the magnetism may affect the processing of the semiconductor wafer or the like on the stage 2.

The second linear motor 220 in which the second magnet portion 240 moves as described above is a so-called moving magnet type linear motor. In this case, the second coil portion 230 that generates the heat due to the flowing current is isolated from the drive target integrated with the stage 2 or the Y-slider 150 (furthermore, in the illustrated example, the second coil portion 230 is thermally isolated from the second drive shaft 200 via the base 4 and the surface plate 3). Therefore, heat transfer to the stage 2 and/or a workpiece such as a semiconductor wafer can be effectively suppressed. This is particularly preferable when the workpiece such as the semiconductor wafer is likely to be affected by the heat or when the stage 2 itself is likely to be deformed by the heat.

In this moving magnet type second linear motor 220, the length of the second coil portion 230 in the Y-axis direction is longer than the length of the second magnet portion 240 in the Y-axis direction. For example, it is preferable that the length of the second coil portion 230 in the Y-axis direction is the length that can cover the movable range of the Y-slider 150 in the Y-axis direction. In addition, it is preferable that the length of the second magnet portion 240 in the Y-axis direction is equal to or shorter than the length of the Y-slider 150 and/or the stage 2 in the Y-axis direction. The relatively short second magnet portion 240 is movable integrally with the Y-slider 150 serving as the drive target in the Y-axis direction within the installation range of the relatively long second coil portion 230.

In the illustrated example, it is preferable that the first linear motor 120 is a moving coil type to reduce the influence of the magnetism on the stage 2 or the like, and it is preferable that the second linear motor 220 is a moving magnet type to reduce the influence of the heat on the stage 2 or the like. In this way, in the stage device 1 according to the present embodiment, it is preferable that the first linear motor 120 and the second linear motor 220 are different types.

On the other hand, in order to further reduce the influence of the magnetism on the stage 2 or the like, the second linear motor 220 may be formed as the moving coil type. Specifically, the second coil portion 230 is provided in the Y-slider 150, and the second magnet portion 240 is provided in the second drive shaft 200 (for example, the base 4) (not illustrated). In this case, the second magnet portion 240 is stationary. Therefore, there is an advantage that fluctuations in the magnetism leaking outward of the second linear motor 220 are small. This is particularly preferable when the processing of the semiconductor wafer or the like on the stage 2 is likely to be affected by the magnetism.

In this moving coil type second linear motor 220, the length of the second coil portion 230 in the Y-axis direction is shorter than the length of the second magnet portion 240 in the Y-axis direction. For example, it is preferable that the length of the second coil portion 230 in the Y-axis direction is equal to or shorter than the length of the Y-slider 150 and/or the stage 2 in the Y-axis direction. In addition, it is preferable that the length of the second magnet portion 240 in the Y-axis direction is the length that can cover the movable range of the Y-slider 150 in the Y-axis direction. The relatively short second coil portion 230 is movable integrally with the Y-slider 150 serving as the drive target in the Y-axis direction within the installation range of the relatively long second magnet portion 240.

Since the pair of second linear motors 220 are provided on both sides in the X-axis direction of the first drive shaft 100 serving as the drive target as described above. In this manner, the drive target can be stably driven in the Y-axis direction while undesirable rotation such as yawing (rotation around the Z-axis) can be effectively suppressed.

Subsequently, a gas floating portion that enables smooth driving of the first drive shaft 100 in the X-axis direction and smooth driving of the second drive shaft 200 in the Y-axis direction will be described.

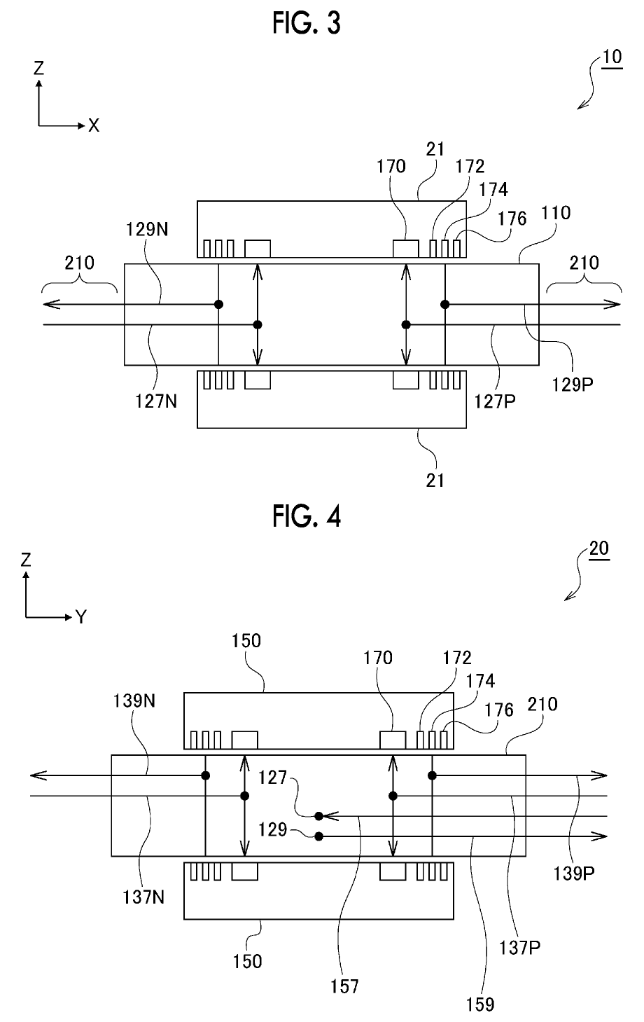

FIG. 3 is a section view schematically illustrating a first gas floating portion 10 that enables the first drive shaft 100 to smoothly drive the X-slider 21 in the X-axis direction by using a floating gas. Specifically, a ZX-cross section of the X-guide 110, which is a main body of the first drive shaft 100, at the center in the Y-axis direction is schematically illustrated. The first gas floating portion 10 causes the X-slider 21 serving as the driven body to float from the X-guide 110 which is the main body of the first drive shaft 100 by using a gas.

An air pad 170 serving as a hydrostatic bearing is formed between the outer peripheral surface of the X-guide 110 and the inner peripheral surface of the X-slider 21 such that the X-slider 21 is smoothly movable along the X-guide 110 in the X-axis direction. The air pad 170 is formed in such a manner that a first floating gas such as compressed air supplied through a first floating pipe 127 provided inside the X-guide 110 which is the main body of the first drive shaft 100 is always supplied between the outer peripheral surface of the X-guide 110 and the inner peripheral surface of the X-slider 21. The X-slider 21 floating from the X-guide 110 by the air pad 170 is smoothly movable in a state of substantially non-contact with the X-guide 110.

It is preferable that the plurality of air pads 170 are provided at symmetrical positions where the center of the X-slider 21 in the X-axis direction and/or the Y-axis direction is pinched from both positive and negative sides in the X-axis direction and/or the Y-axis direction. In addition, it is preferable that the plurality of air pads 170 are provided at symmetrical positions where the X-guide 110 is pinched from both positive and negative sides in the Z-axis direction. The undesirable rotation of the X-slider 21 is effectively suppressed by the symmetrical disposition of the plurality of air pads 170 in the X-axis direction, the Y-axis direction, the Z-axis direction, and the like.

The first floating pipe 127 includes a positive-side first floating pipe 127P and a negative-side first floating pipe 127N. In the example of the present embodiment, the positive-side first floating pipe 127P and the negative-side first floating pipe 127N which are provided inside the X-guide 110 communicate with a floating gas relay pipe provided inside the Y-guide 210, as will be described later. However, the positive-side first floating pipe 127P and the negative-side first floating pipe 127N may communicate with a floating gas supply pipe or a tube (not illustrated) directly and externally attached to the X-guide 110 to supply the floating gas from the outside. Alternatively, a pipe for supplying the floating gas to the air pad 170 of the positive-side first floating pipe 127P, the negative-side first floating pipe 127N, and the like may be provided inside the X-slider 21 instead of being provided inside the X-guide 110. In this case, a floating gas supply pipe or a tube (not illustrated) directly and externally attached to the X-slider 21 to supply the floating gas from the outside may be provided.

For example, the positive-side first floating gas from a pump (not illustrated) is supplied to the air pad 170 on the positive side in the X-axis direction via a positive-side floating gas relay pipe inside the positive-side Y-guide 210 and a positive-side first floating pipe 127P inside the X-guide 110. Similarly, for example, the negative-side first floating gas from a pump (not illustrated) is supplied to the air pad 170 on the negative side in the X-axis direction via a negative-side floating gas relay pipe inside the negative-side Y-guide 210 and a negative-side first floating pipe 127N inside the X-guide 110.

The first floating gas may be supplied from the floating gas relay pipe and the first floating pipe 127 on any one of the positive side and the negative side to the air pads 170 on both the positive side and the negative side. For example, the first floating gas from a pump (not illustrated) may be supplied to the air pads 170 on both the positive side and the negative side via the positive-side floating gas relay pipe inside the positive-side Y-guide 210 and the positive-side first floating pipe 127P inside the X-guide 110. In this case, all or a portion of the negative-side floating gas relay pipe inside the negative-side Y-guide 210 and at least a portion of the negative-side first floating pipe 127N may not be provided on the negative side to which the first floating gas is not supplied.

When the stage device 1 is used inside a vacuum chamber in an internal vacuum state, it is necessary that the first floating gas such as the compressed air supplied to the air pad 170 does not leak into the vacuum chamber. Therefore, in the present embodiment, exhaust grooves 172, 174, and 176 serving as exhaust portions for discharging the first floating gas inside the air pad 170 to the outside of the vacuum chamber accommodating the stage device 1 are provided on the inner peripheral surface of the X-slider 21. As illustrated, the exhaust grooves 172, 174, and 176 are provided at positions where the air pad 170 is pinched from both positive and negative sides in the X-axis direction and/or the Y-axis direction. In other words, the exhaust grooves 172, 174, and 176 are provided outside the air pad 170 on the inner peripheral surface of the X-slider 21.

The exhaust grooves 172, 174, and 176 are provided such that a pressure sequentially decreases from the inside or the center toward the outside, that is, such that a degree of vacuum sequentially increases. For example, the exhaust groove 172 is set to an atmospheric pressure, the exhaust groove 174 is set to a low vacuum, and the exhaust groove 176 is set to a medium vacuum. The exhaust grooves 172, 174, and 176 having different pressures or degrees of vacuum are realized by a plurality of first exhaust pipes 129 (only one is illustrated for convenience in FIG. 3) provided inside the X-guide 110 which is the main body of the first drive shaft 100. Specifically, the first exhaust pipe 129 communicating with the atmosphere or air at the atmospheric pressure is opened at a position facing the exhaust groove 172. In this manner, the exhaust groove 172 has the atmospheric pressure. The first exhaust pipe 129 connected to a low vacuum pump (not illustrated) or the like is opened at a position facing the exhaust groove 174. In this manner, the exhaust groove 174 has a low vacuum. The first exhaust pipe 129 connected to a medium vacuum pump (not illustrated) or the like is opened at a position facing the exhaust groove 176. In this manner, the exhaust groove 176 has a medium vacuum.

The first floating gas in the air pad 170 is sequentially exhausted outward of the vacuum chamber through the atmospheric pressure (exhaust groove 172), the low vacuum (exhaust groove 174), and the medium vacuum (exhaust groove 176) by the plurality of exhaust grooves 172, 174, and 176 and the plurality of first exhaust pipes 129 as described above. Therefore, the first floating gas inside the air pad 170 is effectively prevented from leaking into the vacuum chamber.

In this way, the stage device 1 according to the present embodiment can be used in a vacuum environment such as the vacuum chamber. Here, the vacuum represents a state of a space filled with a gas having a pressure lower than a normal atmospheric pressure. The vacuum is classified into a low vacuum (100 kPa to 100 Pa), a medium vacuum (100 Pa to 0.1 Pa), a high vacuum (0.1 Pa to 10⁻⁵ Pa), an ultra-high vacuum (10⁻⁵ Pa or lower), and the like, depending on a pressure region. The stage device 1 according to the present embodiment may be used in any of the above-described classification sections in the vacuum environment, or may be used in a non-vacuum environment. The stage device 1 according to the present embodiment is particularly suitable for use in a vacuum environment having a low pressure where a high level of cleanliness is required.

The first exhaust pipe 129 includes a positive-side first exhaust pipe 129P and a negative-side first exhaust pipe 129N. In the example of the present embodiment, the positive-side first exhaust pipe 129P and the negative-side first exhaust pipe 129N which are provided inside the X-guide 110 communicate with an exhaust relay pipe provided inside the Y-guide 210, as will be described later. In this case, the first exhaust pipe 129 exhausts the first floating gas to the Y-guide 210 which is the main body of the second drive shaft 200 provided with the exhaust relay pipe. For example, the exhaust relay pipe in the Y-guide 210 is connected to each of the atmosphere, the low vacuum pump, and the medium vacuum pump to realize each of the atmospheric pressure (exhaust groove 172), the low vacuum (exhaust groove 174), and the medium vacuum (exhaust groove 176). However, the positive-side first exhaust pipe 129P and the negative-side first exhaust pipe 129N may communicate with an exhaust pipe or a tube (not illustrated) directly and externally attached to the X-guide 110 to supply the atmospheric pressure, the low vacuum, the medium vacuum, or the like from the outside. Alternatively, a pipe that supplies the atmospheric pressure, the low vacuum, the medium vacuum, or the like, such as the positive-side first exhaust pipe 129P and the negative-side first exhaust pipe 129N, may be provided inside the X-slider 21 instead of being provided inside the X-guide 110. In this case, an exhaust pipe or a tube (not illustrated) directly and externally attached to the X-slider 21 to supply the atmospheric pressure, the low vacuum, the medium vacuum, or the like from the outside may be provided.

The exhaust from the exhaust groove 172 is discharged to the atmosphere via the first exhaust pipe 129 (129P and/or 129N) for the atmospheric pressure inside the X-guide 110 and the exhaust relay pipe for the atmospheric pressure inside the Y-guide 210. The exhaust from the exhaust groove 174 is discharged via the first exhaust pipe 129 (129P and/or 129N) for the low vacuum inside the X-guide 110, the exhaust relay pipe for the low vacuum inside the Y-guide 210, and the low vacuum pump. The exhaust from the exhaust groove 176 is discharged via the first exhaust pipe 129 (129P and/or 129N) for the medium vacuum inside the X-guide 110, the exhaust relay pipe for the medium vacuum inside the Y-guide 210, and the medium vacuum pump.

The exhaust may be performed from the exhaust grooves 172, 174, and 176 on both the positive side and the negative side through the first exhaust pipe 129 and the exhaust relay pipe on any one of the positive side and the negative side. For example, the exhaust may be performed from the exhaust grooves 172, 174, and 176 on both the positive side and the negative side through the positive-side first exhaust pipe 129P inside the X-guide 110 and the positive-side exhaust relay pipe inside the positive-side Y-guide 210. In this case, at least a portion of the negative-side first exhaust pipe 129N and all or a portion of the negative-side exhaust relay pipe inside the negative-side Y-guide 210 do not need to be provided on the negative side where the exhaust is not performed.

FIG. 4 is a section view schematically illustrating a second gas floating portion 20 that enables the second drive shaft 200 to smoothly drive the Y-slider 150 in the Y-axis direction by using the floating gas. Specifically, a YZ-cross section of the Y-guide 210 which is the main body of the second drive shaft 200, at the center in the X-axis direction is schematically illustrated. The same reference numerals will be assigned to the same components as those of the first gas floating portion 10 illustrated in FIG. 3, and repeated description will be omitted. The second gas floating portion 20 causes the Y-slider 150 (portion of the first drive shaft 100) serving as the drive target to float from the Y-guide 210 which is the main body of the second drive shaft 200 by using the gas.

The air pad 170 serving as a hydrostatic bearing is formed between the outer peripheral surface of the Y-guide 210 and the inner peripheral surface of the Y-slider 150 such that the Y-slider 150 is smoothly movable along the Y-guide 210 in the Y-axis direction. The air pad 170 is formed in such a manner that a second floating gas such as the compressed air supplied through the second floating pipe 137 provided inside the Y-guide 210 which is the main body of the second drive shaft 200 is always supplied between the outer peripheral surface of the Y-guide 210 and the inner peripheral surface of the Y-slider 150. Alternatively, a pipe for supplying the floating gas to the air pad 170 of the second floating pipe 137 or the like may be provided inside the Y-slider 150 instead of being provided inside the Y-guide 210. In this case, a floating gas supply pipe or tube (not illustrated) directly and externally attached to the Y-slider 150 to supply the floating gas from the outside may be provided. The Y-slider 150 floating from the Y-guide 210 by the air pad 170 is smoothly movable in a state of substantially non-contact with the Y-guide 210.

It is preferable that the plurality of air pads 170 are provided at symmetrical positions where the center of the Y-slider 150 in the Y-axis direction and/or the X-axis direction is pinched from both positive and negative sides in the Y-axis direction and/or the X-axis direction. In addition, it is preferable that the plurality of air pads 170 are provided at symmetrical positions where the Y-guide 210 is pinched from both positive and negative sides in the Z-axis direction. The undesirable rotation of the Y-slider 150 is effectively suppressed by the symmetrical disposition of the plurality of air pads 170 in the X-axis direction, the Y-axis direction, the Z-axis direction, and the like.

The second floating pipe 137 includes a positive-side second floating pipe 137P and a negative-side second floating pipe 137N. The positive-side second floating pipe 137P and the negative-side second floating pipe 137N are provided inside the Y-guide 210.

For example, a positive-side second floating gas from a pump (not illustrated) is supplied to the air pad 170 on the positive side in the Y-axis direction via the positive-side second floating pipe 137P inside the Y-guide 210. Similarly, for example, a negative-side second floating gas from a pump (not illustrated) is supplied to the air pad 170 on the negative side in the Y-axis direction via the negative-side second floating pipe 137N inside the Y-guide 210.

The second floating gas may be supplied from the second floating pipes 137 on any one of the positive side and the negative side to the air pads 170 on both the positive side and the negative side. For example, the second floating gas from the pump (not illustrated) may be supplied to the air pads 170 on both the positive side and the negative side via the positive-side second floating pipe 137P inside the Y-guide 210. In this case, at least a portion of the negative-side second floating pipe 137N does not need to be provided on the negative side where the second floating gas is not supplied.

As described above with reference to FIG. 3, the first floating pipe 127 that supplies the first floating gas to the air pad 170 in the first gas floating portion 10 communicates with the floating gas relay pipe 157 provided inside the Y-guide 210 in FIG. 4. The floating gas relay pipe 157 is connected to a pump (not illustrated) which is a supply source of the first floating gas. The first floating gas from a pump (not illustrated) is supplied to the air pad 170 in the first gas floating portion 10 via the floating gas relay pipe 157 inside the Y-guide 210 and the first floating pipe 127 inside the X-guide 110. In this way, inside the Y-guide 210 which is the main body of the second drive shaft 200, supply of the second floating gas through the second floating pipe 137 to cause the Y-slider 150 to float, and supply or relay of the first floating gas through the floating gas relay pipe 157 to cause the X-slider 21 to float are simultaneously performed.

When the stage device 1 is used in the vacuum chamber in an internal vacuum state, it is necessary that the second floating gas such as the compressed air supplied to the air pad 170 does not leak into the vacuum chamber. Therefore, in the present embodiment, the exhaust grooves 172, 174, and 176 serving as exhaust portions for discharging the second floating gas inside the air pad 170 to the outside of the vacuum chamber accommodating the stage device 1 are provided on the inner peripheral surface of the Y-slider 150. As illustrated, the exhaust grooves 172, 174, and 176 are provided at positions where the air pad 170 is pinched from both positive and negative sides in the Y-axis direction and/or the X-axis direction. In other words, the exhaust grooves 172, 174, and 176 are provided outside the air pad 170 on the inner peripheral surface of the Y-slider 150.

The exhaust grooves 172, 174, and 176 are provided such that the pressure sequentially decreases from the inside or the center toward the outside, that is, such that a degree of vacuum sequentially increases. For example, the exhaust groove 172 is set to an atmospheric pressure, the exhaust groove 174 is set to a low vacuum, and the exhaust groove 176 is set to a medium vacuum. The exhaust grooves 172, 174, and 176 having different pressures or degrees of vacuum are realized by the plurality of second exhaust pipes 139 (only one is illustrated for convenience in FIG. 4) provided inside the Y-guide 210 which is the main body of the second drive shaft 200. Specifically, the second exhaust pipe 139 communicating with the atmosphere or the air at atmospheric pressure is opened at a position facing the exhaust groove 172. In this manner, the exhaust groove 172 has the atmospheric pressure. The second exhaust pipe 139 connected to a low vacuum pump (not illustrated) or the like is opened at a position facing the exhaust groove 174. In this manner, the exhaust groove 174 has the low vacuum. The second exhaust pipe 139 connected to a medium vacuum pump (not illustrated) or the like is opened at a position facing the exhaust groove 176. In this manner, the exhaust groove 176 has the medium vacuum.

The second floating gas inside the air pad 170 is sequentially exhausted outward of the vacuum chamber through the atmospheric pressure (exhaust groove 172), the low vacuum (exhaust groove 174), and the medium vacuum (exhaust groove 176) by the plurality of exhaust grooves 172, 174, and 176 and the plurality of second exhaust pipes 139 as described above. Therefore, the second floating gas inside the air pad 170 is effectively prevented from leaking into the vacuum chamber.

The second exhaust pipe 139 includes a positive-side second exhaust pipe 139P and a negative-side second exhaust pipe 139N. The positive-side second exhaust pipe 139P and the negative-side second exhaust pipe 139N are provided inside the Y-guide 210. For example, the second exhaust pipes 139 are each connected to the atmosphere, the low vacuum pump, and the medium vacuum pump to realize each of the atmospheric pressure (exhaust groove 172), the low vacuum (exhaust groove 174), and the medium vacuum (exhaust groove 176) described above.

The exhaust from the exhaust groove 172 is discharged to the atmosphere via the second exhaust pipe 139 (139P and/or 139N) for the atmospheric pressure inside the Y-guide 210. Similarly, the exhaust from the exhaust groove 174 is discharged via the second exhaust pipe 139 (139P and/or 139N) for the low vacuum inside the Y-guide 210 and the low vacuum pump. Similarly, the exhaust from the exhaust groove 176 is discharged via the second exhaust pipe 139 (139P and/or 139N) for the medium vacuum inside the Y-guide 210 and the medium vacuum pump.

The exhaust may be performed from the exhaust grooves 172, 174, and 176 on both the positive side and the negative side through the second exhaust pipe 139 on any one of the positive side and the negative side. For example, the exhaust may be performed from the exhaust grooves 172, 174, and 176 on both the positive side and the negative side through the positive-side second exhaust pipe 139P inside the Y-guide 210. In this case, at least a portion of the negative-side second exhaust pipe 139N does not need to be provided on the negative side where the exhaust is not performed.

As described above with reference to FIG. 3, the first exhaust pipe 129 that exhausts the first floating gas from the exhaust grooves 172, 174, and 176 in the first gas floating portion 10 communicates with the exhaust relay pipe 159 provided inside the Y-guide 210 in FIG. 4. For example, the exhaust relay pipe 159 is connected to each of the atmosphere, the low vacuum pump, and the medium vacuum pump to realize each of the atmospheric pressure (exhaust groove 172 in FIG. 3), the low vacuum (exhaust groove 174 in FIG. 3), and the medium vacuum (exhaust groove 176 in FIG. 3) described above.

In this way, the exhaust (first floating gas) from the exhaust groove 172 in the first gas floating portion 10 is discharged to the atmosphere via the first exhaust pipe 129 (129P and/or 129N) for the atmospheric pressure inside the X-guide 110 and the exhaust relay pipe 159 for the atmospheric pressure inside the Y-guide 210. The exhaust (first floating gas) from the exhaust groove 174 in the first gas floating portion 10 is discharged via the first exhaust pipe 129 (129P and/or 129N) for the low vacuum inside the X-guide 110, the exhaust relay pipe 159 for the low vacuum inside the Y-guide 210, and the low vacuum pump. The exhaust (first floating gas) from the exhaust groove 176 in the first gas floating portion 10 is discharged via the first exhaust pipe 129 (129P and/or 129N) for the medium vacuum inside the X-guide 110, the exhaust relay pipe 159 for the medium vacuum inside the Y-guide 210, and the medium vacuum pump.

As described above, inside the Y-guide 210 which is the main body of the second drive shaft 200, the exhaust of the second gas floating portion 20 through the second exhaust pipe 139 (atmospheric pressure/low vacuum/medium vacuum) and the exhaust of the first gas floating portion 10 through the exhaust relay pipe 159 (atmospheric pressure/low vacuum/medium vacuum) are simultaneously performed. In FIG. 4, for convenience, the second exhaust pipe 139 and the exhaust relay pipe 159 are illustrated as separate bodies. However, since the purpose of the exhaust (atmospheric pressure/low vacuum/medium vacuum) is common, the second exhaust pipe 139 and the exhaust relay pipe 159 may be integrally formed (the low vacuum pump or the medium vacuum pump connected to the second exhaust pipe 139 and the exhaust relay pipe 159 can be used in common).

According to the above-described embodiment, high responsiveness can be realized when the stage device is driven by the first drive shaft 100 and the second drive shaft 200 which drive the driven body such as the X-slider 21 and the first drive shaft 100 by using the magnetism (first linear motor 120 and second linear motor 220), and a highly smooth operation can be realized when the stage device is driven by the first gas floating portion 10 and the second gas floating portion 20 which cause the driven body such as the X-slider 21 and the first drive shaft 100 to float by using the gas. Since the first gas floating portion 10 and the second gas floating portion 20 include an exhaust mechanism for the floating gas, the stage device 1 according to the present embodiment can be used in the vacuum environment such as the vacuum chamber.

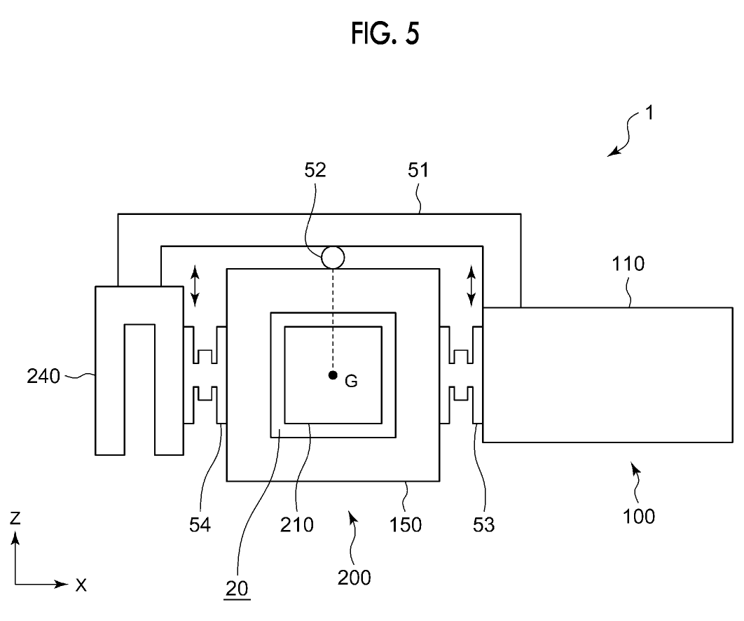

Subsequently, a connection portion between the first drive shaft 100 and the second drive shaft 200 will be described in detail. FIG. 5 is a ZX-plane view schematically illustrating the connection portion between the first drive shaft 100 and the second drive shaft 200. In addition, a connection member 51, a load receiving portion 52, a first attachment tool 53, a second attachment tool 54, and the like which are illustrated in FIG. 5 are omitted in FIG. 1.

As schematically illustrated in FIG. 5, an end portion of the X-guide 110 in the first drive shaft 100 on the −X side (left side in FIG. 5) is provided to face one side surface of the Y-slider 150 on the +X side (right side in FIG. 5), and the second magnet portion 240 as the movable element of the second linear motor 220 is provided to face the other side surface of the Y-slider 150 on the −X side.

An arm-shaped connection member 51 that connects an end portion of the X-guide 110 in the first drive shaft 100 on the −X side and the second magnet portion 240 serving as the movable element of the second linear motor 220 is provided above (+Z side) the Y-slider 150. It is preferable that the connection member 51 connects an upper surface of the end portion of the X-guide 110 on the −X side and an upper surface of the second magnet portion 240 to each other.

A load receiving portion 52 that receives a load from the connection member 51 is provided between the upper surface of the Y-slider 150 and the lower surface of the connection member 51. Here, since the X-guide 110 and the second magnet portion 240 are connected to both end portions of the connection member 51, the load receiving portion 52 receives at least a portion of the load of the X-guide 110 and the second magnet portion 240 in addition to the load of the connection member 51 itself. At least a portion of the load of the X-guide 110 may be received by a suitable load support structure (not illustrated). On the other hand, the load of the second magnet portion 240 is substantially received only by the load receiving portion 52 via the connection member 51.

When the second magnet portion 240 is directly attached to the side surface of the Y-slider 150 on the −X side (without interposing the second attachment tool 54 to be described later), the Y-slider 150 may rotate (roll) in a counterclockwise direction in FIG. 5 due to the load of the second magnet portion 240. In particular, when the second gas floating portion 20 serving as a hydrostatic bearing is formed between the inner peripheral surface of the Y-slider 150 and the outer peripheral surface of the Y-guide 210, the Y-slider 150 is likely to be affected by undesirable rolling.

Therefore, in the present embodiment, a configuration is adopted in which the load of the second magnet portion 240 is received only by the load receiving portion 52 instead of being received by the side surface of the Y-slider 150. In particular, as schematically illustrated in FIG. 5, when a point at which the load is received by the load receiving portion 52 is located directly above the center of gravity G of the Y-slider 150, the load does not cause undesirable rolling of the Y-slider 150.

However, the point at which the load is received by the load receiving portion 52 may be located within a predetermined range (for example, a range of 0.5 or smaller, a range of 0.3 or smaller, a range of 0.1 or smaller, or a range of 0.05 or smaller when the length of the Y-slider 150 in the X-axis direction is set to 1) formed around the center of gravity G of the Y-slider 150 in the X-axis direction. In addition, when the point at which the load is received by the load receiving portion 52 is disposed symmetrically with respect to the center of gravity G of the Y-slider 150 in the Y-axis direction, undesirable pitching rotation (rotation around the X-axis) of the Y-slider can also be reduced.

It is preferable that the load receiving portion 52 as described above releases a force in the X-axis direction and/or the Y-axis direction while receiving the load in the Z-axis direction. For this purpose, the load receiving portion 52 may be formed by using a ball rotatable in the X-axis direction and/or the Y-axis direction on the upper surface of the Y-slider 150. For example, the load receiving portion 52 may be formed by using a ball receiver, a ball bearing, or the like.

The connection member 51 is not limited to an integral member as illustrated, and may be divided into a plurality of members. For example, a first connection member connected to the X-guide 110 and extending to the upper side of the Y-slider 150 and a second connection member connected to the second magnet portion 240 and extending to the upper side of the Y-slider 150 may be separately provided. In this case, a first load receiving portion such as a ball receiver may be provided between the first connection member and the upper surface of the Y-slider 150, and a second load receiving portion such as a ball receiver may be provided between the second connection member and the upper surface of the Y-slider 150. In addition, only one of the first connection member/first load receiving portion and the second connection member/second load receiving portion may be provided.

The side surface of the Y-slider 150 on the +X side and the end portion of the X-guide 110 on the −X side may be attached to each other by the first attachment tool 53 that is deformable in a direction in which the load in the Z-axis direction is released. Similarly, the side surface of the Y-slider 150 on the −X side and the side surface of the second magnet portion 240 on the +X side may be attached to each other by the second attachment tool 54 that is deformable in the direction in which the load in the Z-axis direction is released.

A hinge or the first attachment tool 53 having a hinge shape is deformable in the Z-axis direction as schematically illustrated by a bidirectional arrow, and allows a relative displacement in the Z-axis direction between the X-guide 110 and the Y-slider 150. On the other hand, the first attachment tool 53 is substantially non-deformable in the X-axis direction and/or the Y-axis direction, and does not allow the relative displacement in the X-axis direction and/or the Y-axis direction between the X-guide 110 and the Y-slider 150. When this first attachment tool 53 receives the load in the Z-axis direction from the X-guide 110, the first attachment tool 53 deforms to release the load. Therefore, the load is less likely to be transmitted to the side surface of the Y-slider 150 on the +X side. Therefore, it is possible to prevent the undesirable rolling of the Y-slider 150 which is caused by the load.

Similarly, a hinge or the second attachment tool 54 having a hinge shape is deformable in the Z-axis direction as schematically illustrated by a bidirectional arrow, and allows a relative displacement in the Z-axis direction between the second magnet portion 240 and the Y-slider 150. On the other hand, the second attachment tool 54 is substantially non-deformable in the X-axis direction and/or the Y-axis direction, and does not allow the relative displacement in the X-axis direction and/or the Y-axis direction between the second magnet portion 240 and the Y-slider 150. When this second attachment tool 54 receives the load in the Z-axis direction from the second magnet portion 240, the second attachment tool 54 deforms to release the load. Therefore, the load is less likely to be transmitted to the side surface of the Y-slider 150 on the −X side. Therefore, it is possible to prevent the undesirable rolling of the Y-slider 150 which is caused by the load.

The first attachment tool 53 and/or the second attachment tool 54 are not limited to the illustrated configuration, and may be formed by a mechanical component having any principle or structure as long as a desired function can be realized to allow a relative displacement in the Z-axis direction and not to allow at least a displacement in the X-axis direction. For example, the first attachment tool 53 and/or the second attachment tool 54 may be formed by using a ball bearing including a ball that is rotatable to allow the relative displacement in the Z-axis direction.

Hitherto, the present disclosure has been described with reference to the embodiments. Various modification examples are possible in combinations of respective components and respective processes in the embodiments as examples, and it is obvious to those skilled in the art that such modification examples are included in the scope of the present disclosure.

In the above-described embodiment, the stage device 1 of the gas guide type or the air guide type in which the X-slider 21 and/or the Y-slider 150 are guided in a non-contact state by the first gas floating portion 10 and/or the second gas floating portion 20 serving as the hydrostatic bearing has been described as an example. However, the stage device 1 may include a guide mechanism or the like using a mechanical linear guide.

In addition, the configuration, the operation, and the function of each device and each method which are described in the embodiment can be realized by hardware resources or software resources, or by cooperation between the hardware resources and the software resources. As the hardware resources, for example, a processor, a ROM, a RAM, and various integrated circuits can be used. As the software resources, for example, programs such as an operating system and an application can be used.

It should be understood that the invention is not limited to the above-described embodiment, but may be modified into various forms on the basis of the spirit of the invention. Additionally, the modifications are included in the scope of the invention.

What is claimed is:

1. A drive device comprising:
a first drive shaft that drives a driven body in a first direction; and
a second drive shaft that drives the driven body and the first drive shaft in a second direction intersecting the first direction,
wherein the second drive shaft includes a guide extending in the second direction and a slider movable along the guide,
an end portion of the first drive shaft is provided to face one side surface of the slider, and a movable element of a linear motor that applies a driving force in the second direction to the slider is provided to face the other side surface of the slider,
a connection member that connects the end portion of the first drive shaft and the movable element of the linear motor is provided above the slider, and
a load receiving portion that receives a load from the connection member is provided between an upper surface of the slider and the connection member.

2. The drive device according to claim 1,
wherein the load receiving portion is a ball rotatable in at least one of the first direction and the second direction on the upper surface of the slider.

3. The drive device according to claim 1,
wherein the one side surface of the slider and the end portion of the first drive shaft are attached to each other by a first attachment tool that is deformable in a direction in which the load is released.

4. The drive device according to claim 1,
wherein the other side surface of the slider and a side surface of the movable element of the linear motor are attached to each other by a second attachment tool that is deformable in a direction in which the load is released.

5. The drive device according to claim 1,
wherein the linear motor is configured as a drive unit between the driven body and the second drive shaft to drive the driven body along the second direction.

6. The drive device according to claim 5,
wherein another linear motor serving as the drive unit is formed between the driven body and the first drive shaft to drive the driven body along the first direction.

7. The drive device according to claim 6,
wherein the other linear motor includes a first coil portion including a plurality of coils, and a first magnet portion including a plurality of magnets, and
the linear motor includes a second coil portion including a plurality of coils, and a second magnet portion including a plurality of magnets.

8. The drive device according to claim 7,
wherein a pair of the sliders are provided, and the first magnet portion is attached to a columnar beam portion laid between the pair of sliders.

9. The drive device according to claim 8,
wherein the first coil portion is driven in the first direction by magnetic interaction with the first magnet portion.

10. The drive device according to claim 7,
wherein the connection member is connected to an upper surface of the movable element of the linear motor.

11. The drive device according to claim 10,
wherein the connection member is separately provided with a first connection member connected to the guide and extending to an upper side of the slider, and a second connection member connected to the second magnet portion of the linear motor and extending to the upper side of the slider.

12. The drive device according to claim 1, further comprising:
a gas floating portion that causes the slider to float from the guide by using a gas.

13. A positioning device that positions the driven body by using the drive device according to claim 1.

14. A processing device that performs predetermined processing on a workpiece disposed on the driven body positioned by the positioning device according to claim 13.

15. A device manufacturing method of manufacturing a device through the processing performed by the processing device according to claim 14.
